(19) United States
(12) Patent Application Publication
(10) Pub. No.: US 2002/0112789 A1
(43) Pub. Date: Aug. 22, 2002

(54) Refractory metal plates with uniform texture and methods of making the same

(75) Inventors: Peter R. Jepson, Newbury, MA (US); Henning Uhlenhut, Cambridge, MA (US); Prabhat Kumar, Framingham, MA (US)

Correspondence Address: PERKINS, SMITH & COHEN LLP, ONE BEACON STREET, 30TH FLOOR, BOSTON, MA, 02108, US

(73) Assignee: H.C. Starck, Inc.

(21) Appl. No.: 10/079,286

(22) Filed: Feb. 20, 2002

Related U.S. Application Data
(60) Provisional application No. 60/269,983, filed on Feb. 20, 2001.

(51) Int. Cl. C22C 27/02; C23C 14/34; C21C 1/00

(52) U.S. Cl. 148/422; 204/298.12; 204/298.13; 148/538; 148/557; 148/668; 148/676; 148/677

(57) ABSTRACT

A method (10) of forming sputtering target (11) from ingots of tantalum or niobium of requisite purity by the process of cutting the ingot to short lengths (12) and pressure working (14, 22, 30, 34) the ingot along alternating essentially orthogonal work axes. Intermediate anneals (18, 26, 38) are applied as necessary to establish a uniform texture thickness-wise and area-wide throughout the target, including the center. The uniform texture is a substantially constant mix of grains with orientation {100} and {111}, thereby improving sputtering performance by providing a more predictable sputter rate to control film thickness.

### CROSS REFERENCE TO RELATED APPLICATIONS

This application claims priority of Provisional Application No. 60/269,983, entitled “REFRACTORY METAL PLATES WITH UNIFORM TEXTURE” filed on Feb. 20, 2001, and which is incorporated herein by reference.

### FIELD OF THE INVENTION

This invention relates generally to improved refractory metal plates usable as sputtering targets and for other purposes to form a plate with high purity, fine grain-size, high-strength, uniform texture structure.

### BACKGROUND OF THE INVENTION

Sputter targets are used in a plasma sputter process to produce thin metal films that are used in various applications, for example as a surface on which vapor bubbles are formed in an ink-jet printer, and for another example, as a barrier layer between copper and silicon in an integrated electronic circuit. Thin films of tantalum oxide are also of practical value, for example in wavelength-division-multiplex (WDM) devices, and, potentially, in electrical capacitors.

Refractory metal sputtering targets exemplify a broader need for microstructural uniformity in refractory metal plates. With targets made by prior art, the heterogeneity of texture found in the sputtering target plate manufactured with known processes cause unpredictability in the sputtering rate (defined as the number of metal atoms sputtered onto the substrate per impinging sputter gas, such as argon ion). Also, heterogeneity of texture causes heterogeneity of the direction in which sputtered atoms leave the target. Unpredictability of sputtering rate and sputtering direction causes variation of the thickness of the film produced from point to point on the substrate, and also causes variation of average thickness of the film produced on the substrate from substrate to sustrate, and from target to target.

In many sputtering applications, the thickness of the film is of prime importance and needs to be controlled closely. In integrated circuits, for example, too thin a film will not provide a barrier, and too thick a film will block a via or trench. In WDM devices, the tantalum oxide layer thickness needs to be very close to one-quarter of a wavelength of the light passing through it. If the thickness of the film deposited is not within the range specified by the designer, the device will not be fit for service, and the total cost of manufacture up to the point of test is lost, since no repair or rework is normally possible.

The aspect of sputtering performance which is most hard to achieve is uniformity of thickness of the thin film produced on a substrate over its whole area, which is usually of the same shape as the target, but somewhat smaller. Typically, the target and substrate are parallel. The thickness of the thin film at any given point is a result of the atoms that have landed at that point. Most of those atoms will have come from a circular area of the target centered directly opposite the given point. That circular area on the target will be of the order of 1 cm radius. Therefore, if the sputtering rate of such a circle is the same wherever the circle lies on the surface of the target, a thin film of perfectly uniform thickness will be deposited, unless there are features of the equipment or its operation which cause non-uniformity.

The sputtering rate of such a circle, defined as the average number of atoms sputtered from it per second, will be an integral of the number of atoms sputtered from each grain within the circle. Grains with different orientations sputter at different rates. Thus if circle #1 is made up predominantly of grains with orientation A, where A is a slow-sputtering orientation, it will have an overall sputtering rate slower than circle #2, if circle #2 is made up predominantly of grains with orientation B, where B is a fast-sputtering orientation. However, if each circle is made up of the same mix of grains (for example, predominantly A, or for another example, an constant mix of grains with orientation A and grains with orientation B), the sputtering performance will improve. Therefore, a uniform texture provides a more controlled film thickness because the sputter rate is more predictable.

U.S. Pat. No. 6,331,233 in Turner asserts uniform texture throughout the plate thickness from the outer edge to the center of the plate. However, the strain history of the material at the center is different from that at the edge. The difference occurs during “Deformation Stage 2,” when the material is upset-forged. During upset forging, the material at the edge or high radius gets a moderate level of strain. The material at the center of the plate or low radius gets a low level of strain near the top or bottom surface and a high level of strain if it is at mid-thickness. Even after annealing, rolling and re-annealing, the difference in strain would be expected to affect the texture.

Even with state-of-the-art sputtering equipment, it is impossible to control the variation of thickness of the thin film from one point on the substrate to another using targets with non-uniform properties. Partial, but not total, control of variation of thickness from substrate to substrate, and from target to target, is possible using test-pieces. Use of test-pieces, however, is time-consuming and costly. Use of forging techniques, such as upset-and-forge-back, with recrystallization heat-treatments that introduces redundant work and thereby improves homogeneity of microstructure is well known. However, such techniques are susceptible to cause various types of defect in the worked metal, for example cracks, folds and mis-shapes, any of which will reduce the proportion of the worked metal which can be used as targets (i.e. reduce the yield). The propensity of the material to crack is often reduced by heating it to a temperature in the region of 500° F. to 600° F. for the forging operations, but such heating is expensive, makes the work-piece harder to handle (so its final shape is further from the desired shape), and may result in an increase in oxygen content, particularly near the surface. Also, other forging techniques (those generally known as upset-bar forging) give product with texture that, although axi-symmetric, varies with radius, from the center out to the edge. Use of powder-metallurgy techniques to achieve uniform texture is also known. However, these techniques are generally not preferred because of higher cost, and because consolidated-powder parts may include voids, and may include non-metallic inclusions, both of which are undesirable for sputtering performance.

For the purpose of the invention, the texture is described as uniform when the texture of one area of an article is not measurably different from that of any other area of the article, except as expected from statistical theory. The uniform texture is not dependent on the size of the article or size of the area.

It is therefore an object of the present invention to provide a sputtering target that improves the predictability of the thickness of the films produced, and thus improve the ease of use of the targets.

It is a further object of the invention to provide classes of tantalum and niobium products of enhanced microstructural uniformity and method of making the same.

It is a further object of the present invention to provide a sputtering target manufactured from a given mass of tantalum ingot, thus improving the cost-efficiency of the process.

### SUMMARY OF THE INVENTION

The present invention comprises a method of forming sputtering targets and other plate products from ingots of refractory metals of requisite purity by the process of cutting the ingot to short length pieces and pressure working the pieces along alternating essentially orthogonal work axes. Intermediate anneals are applied as necessary to establish a uniform texture throughout the target, including the center. The uniform texture is a substantially constant mix of grains with orientation {100} and {111}, where these sets of numbers refer to the Miller indices of the set of crystallographic plane that is parallel or nearly parallel to the sputtered surface. The constant mix of grain orientation thereby improves sputtering performance by providing a more predictable sputter rate to control film thickness.

Additionally, the present invention offers a process that produces a high purity refractory metal material having a unique combination of fine grain structure and uniform texture.

The invention is applicable to plates of flat or curved forms (including roll-up to cylinder or semi-circular or arc or conical forms). The plates can be used to advantage on account of their microstructures and grain uniformity as sputtering, furnace parts, aerospace and engine parts, as products of containers and patches for highly corrosive chemical environments. The plates can also be unbroken or can be drilled with holes or can be an expanded mesh (slit and edges pulled).

Other objects, features and advantages will be apparent from the following detailed description of preferred embodiments taken in conjunction with the accompanying drawings in which:

### BRIEF DESCRIPTION OF THE DRAWINGS

FIG. 1 is a flow chart of the process of a preferred embodiment of the present invention;

FIG. 2 is a photograph of a tantalum target made according to the FIG. 1 process;

FIGS. 3 and 4 are similar photos of used tantalum targets made with coarse-grained or banded texture material;

FIG. 5 is a magnified photograph (400 μm scale-bar) illustrating the grain orientation in imaging microscope shots of a partial cross-section of a target, showing the orientation of each grain relative to the normal direction according to the present invention;

FIG. 6 is a magnified photograph (400 μm scale-bar) illustrating the grain orientation in imaging microscope shots of a partial cross-section of a target, showing the orientation of each grain relative to within plane direction according to the present invention;

FIG. 7 is a magnified photograph (500 μm scale-bar) illustrating the grain orientation in imaging microscope shots of a partial cross-section of a target, showing the orientation of each grain relative to the normal direction according to the prior art;

FIG. 8 is a photograph illustrating a macro-etched surface of a plate formed according to a known prior art process illustrating the non-uniformity of the surface texture; and

FIG. 9 is a photograph illustrating a macro-etched surface of a plate formed according to the present invention illustrating the uniformity of the surface texture.

### DETAILED DESCRIPTION OF PREFERRED EMBODIMENTS

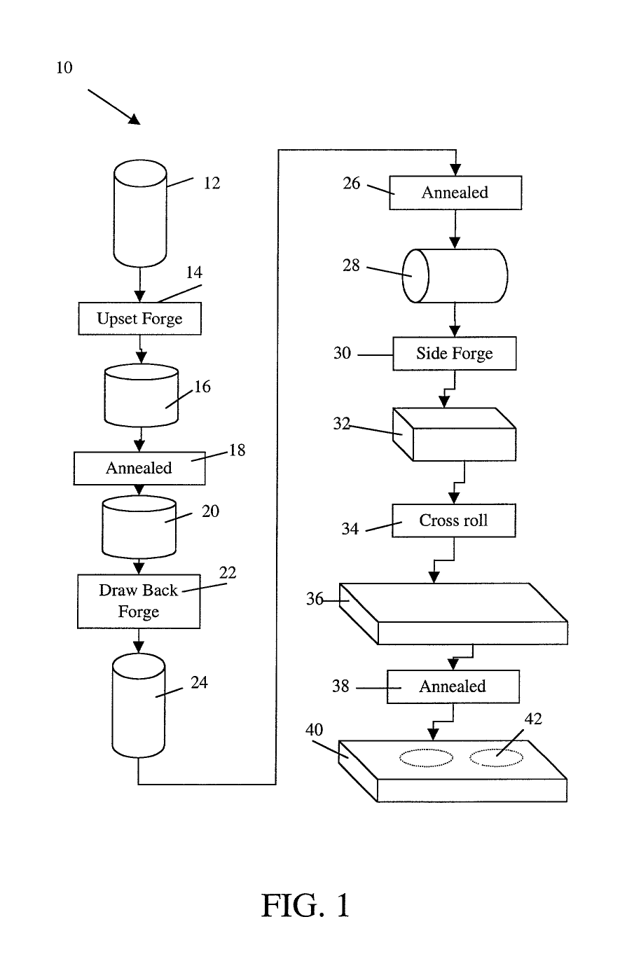

Now referring to FIG. 1, practice of a preferred embodiment of the present invention (method steps 10) starts with a refractory metal ingot 11, preferably tantalum ingot, typically of 8″ diameter of very high purity, preferably 99.999%, with an impurity content suitable for the end use. After cleaning the surface of the ingot by machining, the ingot is cut into initial workpieces 12 of lengths between 1.5 times and 3 times the diameter, or approximately 12 inches to 24 inches. The first forging operation (step 14) reduces each initial workpiece 12 along its longitudinal axis by 35 to 50% to form first forged workpiece 16. First forged workpiece 16 is then annealed (step 18) at high temperature, preferably 1370° C., in vacuum or inert gas to cause recrystallization to produce a second workpiece form 20. The second forging operation (step 22) is then applied to forge the second workpiece form 20 in the longitudinal axis substantially back to approximately the diameter of initial workpiece 12, ranging from 80% to 120% of the diameter of initial workpiece 12. Second workpiece form 20 is laid on its side and flat or curved dies, such as swaging dies, are used to draw back forge in second forging operation (step 22) the second workpiece form 20 to form third workpiece form 24. This is done by impacting with sufficient force to substantially regain the original shape of initial workpiece 12. Second workpiece form 20 is turned between forging cycles for even cold working to induce a constant strain through the piece. All forging is done at room temperature with allowance for natural heating of the workpiece. However, it is preferred that the workpiece not exceed 800° F. All forging is preferably done on a press, rather than a hammer, to reduce the strain rate and allow better control of the shape of the workpiece. Third workpiece form 24 is annealed (step 26) at appropriate temperature for the metal, preferably 875° C. for tantalum and its alloys, in vacuum or inert gas to recrystallize a fourth workpiece form 28. The upset-forge-back cycle (steps 14 and 22) may be repeated as many times as necessary to achieve uniform texture of the plate.

Where appropriate to refine microstructure, or if necessary to avoid cracks, or excessive press loads, extra annealing treatments, at a lower temperature such as 1065° C., may be used at any point during the forging process.

A third forging operation (step 30), preferably side forge, flattens the fourth workpiece form 28 to form sheetbar 32, preferably approximately 4″ thick. The sheetbar is cross-rolled (step 34) to reduce its thickness, typically ranging from 0.25 inches to 0.5 inches, to form plate 36. Cross-rolling (step 34) is arranged such that approximately equal strain in two orthogonal directions is achieved. Following the cross-rolling, plate 36 is annealed (step 38) at a relatively low temperature ranging from 875° C. to 1065° C. to form plate 40 of fully-recrystallized fine grain structure and uniform texture. Subsequently, the component shape 42 will be cut from the plate and bonded to a backing plate assembled in sputtering equipment for use as a sputtering target.

One embodiment of the invention preferably utilizes two upset-forgeback steps, performed on a press and one extra annealing cycle after the second upset-forgeback cycle before flattening to a slab.

The effectiveness and advantages of the products and processes of the present invention will be further illustrated by the following non-limiting examples.

### EXAMPLE 1

This example illustrates a product, made by a conventional prior art method (side-forging and uni-directional rolling of an ingot section), having an average grain size 30 μm linear intercept and a banded texture, as illustrated in FIG. 7.

### EXAMPLE 2

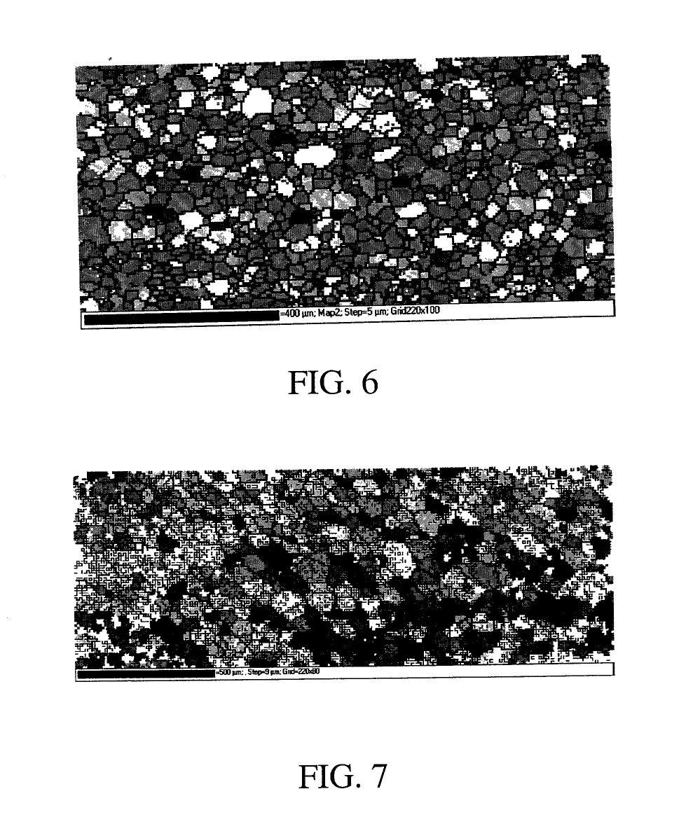

A tantalum plate, having a normal thickness and approximately 99.99% purity, was made by a preferred embodiment process of the present invention as described above and illustrated in FIG. 1. A tantalum ingot of about 8″ diameter was cut into workpieces approximately 1.5 to 3 times the ingot diameter. The workpieces were upset forged by about 40% of original length and annealed to about 1370° C. Next, the workpieces were drawback forged to around the original 8″ diameter, re-upset by approximately 40% of original length, drawn back to about 7.25″ diameter, and annealed at atmosphere of about 1065° C. The workpieces were side forged to a sheetbar of about 4″ thickness, cross rolled to a plate of about 0.500″ thickness, and annealed at atmosphere of about 1065° C. The resulting plate had an average grain size of 30 μm linear intercept and a uniform texture without banding as illustrated in FIGS. 5 and 6.

### EXAMPLE 3

A tantalum plate made by the same process as Example 2 but with a tantalum ingot of 99.999% purity. The resultant plate has an average grain size of 35 μm linear intercept and the texture is uniform without banding.

### EXAMPLE 4

It would be feasible to apply the same process as Example 2, but with a tantalum ingot of 99.999% purity and a lower final annealing temperature of about 875° C. The resultant plate would have an average grain size of 15 μm linear intercept due to the lower annealing temperature and low levels of impurity. The uniform texture is expected since the process of Example 2 has demonstrated texture without banding with substantially the same material.

### EXAMPLE 5

It would be feasible to apply the same process as Example 2, but with a tantalum ingot of 99.999% purity and the rolled thickness is around 0.800″. The resultant plate would have an average grain size of 38 μm linear intercept. The texture is expected to be uniform without banding since the preferred invention ensures texture uniformity even when the strain introduced during rolling is lower than normal.

### EXAMPLE 6

It would be feasible to apply the same process as Example 2, but with a niobium ingot of 99.99% purity. The niobium plate of 0.500″ thickness is expected to have an average grain size of 30μm linear intercept and a uniform texture without banding based on the comparable results of tantalum. The niobium plate is expected to perform similarly to the tantalum plate because their physical characteristics are similar.

### EXAMPLE 7

An alternative embodiment replaces the upset-drawback forging operations process with the well-known process of Equal Channel Angular Extrusion (ECAE); see e.g. U.S. Pat. Nos. 5,400,633, 5,513,512, 5,600,989 and published U.S. applications 2001/0001401, 2001/0054457, 2002/0000272, and 2002/0007880 of Segal et al. The ECAE process includes four C-type passes, anneal at 800° C., four C-type passes, and anneal at 800° C. with 99.99% purity tantalum. The resultant product has an average grain size 8 μm linear intercept.

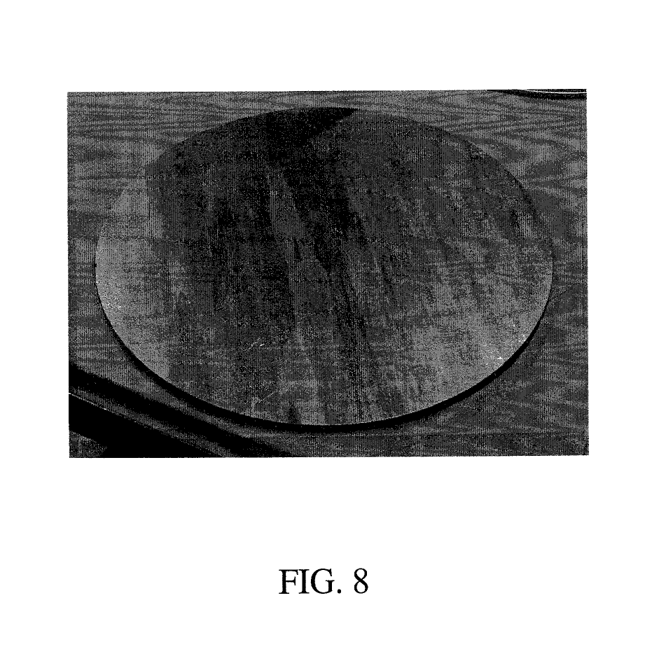

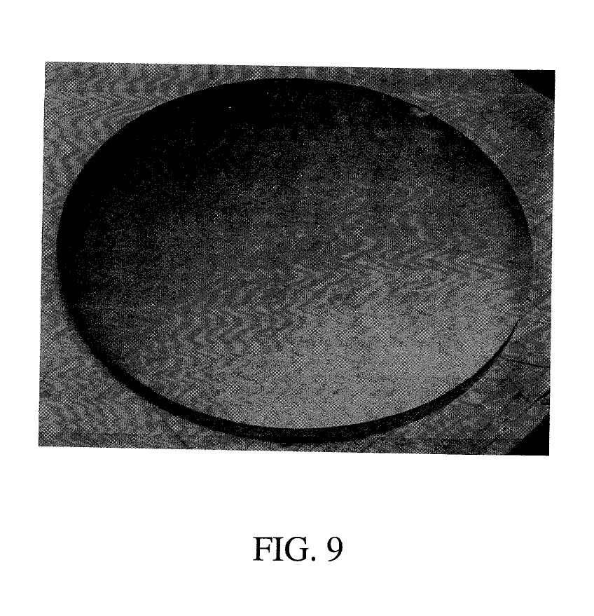

The uniformity of the microstructure, e.g., grain size and texture, is shown in FIGS. 5 and 6 to have improved grain orientation than with the prior art (a uniform patterns of similar random distribution), shown in FIG. 7 (in-homogeneity with non-random distribution). Another way of illustrating the uniformity is by examining the macrostructure of the plate surface, which is revealed by etching in an acid solution containing hydrofluoric acid. The improved process is illustrated in FIG. 9 contrasted to the prior art process represented in FIG. 8.

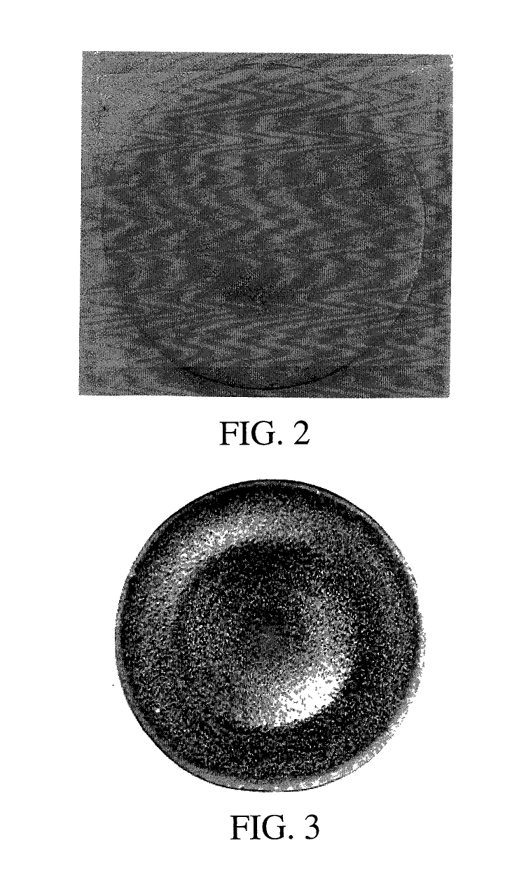

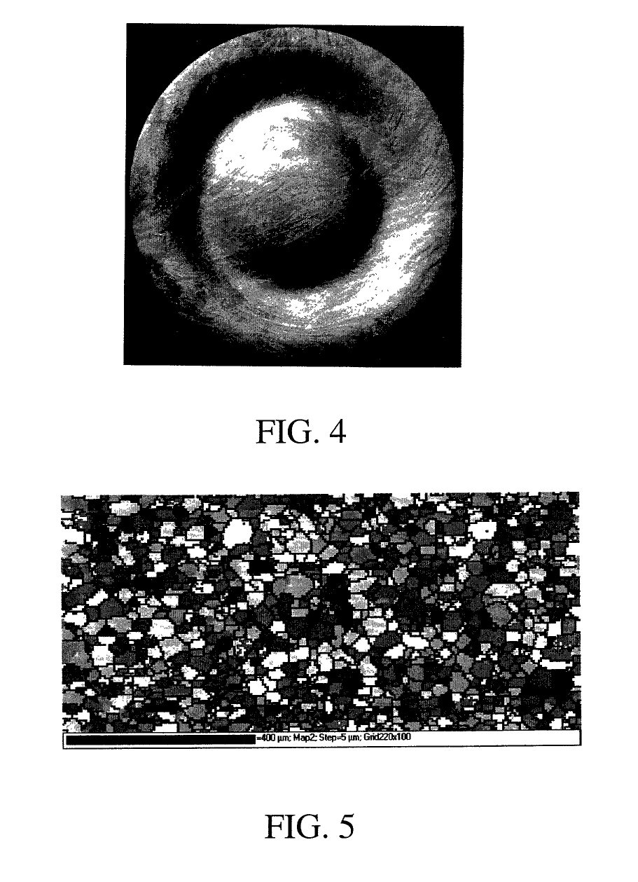

As a result of the uniform texture, the surface of the used sputtering target, as illustrated in FIG. 2, has a uniform appearance, in contrast to the speckled appearance caused by coarse grains or swirling pattern caused by banded texture, common with targets made by prior art, illustrated in FIGS. 3 and 4. In particular, the texture is uniform across the entire plate and uniform through the thickness from the center of the plate to the edge of the plate with no preferred direction within the plate, such as predominantly {100} or {111}. The uniform texture is a substantially constant mix of {100} and {111} crystallographic orientations. The distribution of {100} and {111} crystallographic orientations in any given plane of the plate (orthogonal or diagonal to the thickness) varies less than 30 percent across the surface of such plane and the variation across any thickness less than 30 percent. Plates of thickness less than 0.5″ will be of predominantly {111} and plates of thickness of at least 0.5″ will be of predominantly {100}. Additionally, FIG. 2 illustrates the coarse grained material inherent to the prior art process.

Also, the uniform texture is combined with a fine grain size, typically ASTM 7 to 8.8, when measured per test method ASTM E112. The present invention provides plates up to at least 0.8″ thick to be made with these desirable properties. In prior art, the uniformity of the texture and grain size, and the fineness of the grain, deteriorated with thickness over about 0.5″.

The introduction of a first intermediate anneal after the first upset-forge operation results in a much-decreased propensity of the material to crack in the subsequent metalworking operations. It also removes the need to heat the material for subsequent forging operations.

Reference to each of tantalum and niobium includes its alloys including tantalum-niobium alloys as well as other alloys of each, and also laminates and other composites of each with other materials. The invention applies to form and use of these metals and derivatives (such as oxides) as well as methods of producing the same. The uses of the plates or other forms of the metals include sputtering targets usage but can also include direct use of the plates for chemical, medical, electrical, high temperature resistance applications (furnace parts, aerospace foils, turbine blades).

It will now be apparent to those skilled in the art that other embodiments, improvements, details, and uses can be made consistent with the letter and spirit of the foregoing disclosure and within the scope of this patent, which is limited only by the following claims, construed in accordance with the patent law, including the doctrine of equivalents.

What is claimed is:

1. A refractory metal plate having a thickness, a center, and an edge comprising a uniform texture through said thickness from said center to said edge.

2. The refractory metal plate as defined in claim 1, wherein said uniform texture is substantially an constant mix of {100} and {111} crystallographic orientations.

3. The refractory metal plate as defined in claim 1, further comprising an average grain size of less than 40 microns.

4. The refractory metal plate as defined in claim 1 comprising at least 99.99% tantalum.

5. The refractory metal plate as defined in claim 1 comprising at least 99.999% tantalum.

6. The refractory metal plate as defined in claim 1 comprising at least 99.99% niobium.

7. The refractory metal plate as defined in claim 1 comprising at least 99.999% niobium.

8. A method of making a sputtering target comprising the steps of:
a) providing an ingot with a length-to-diameter ratio up to 3;
b) cold forging the ingot with reductions and elongations sufficient for desired fine grain and texture;
c) subjecting the cold forged product to cross-rolling; and
d) manufacturing the cross-rolled product into a sputtering target.

9. A method for producing a refractory metal plate comprising at least four reducing operations and at least three anneal heat treat operations at temperatures above recrystallization temperature.

10. The method for producing a refractory metal plate as defined in claim 9, further comprising the step of providing a refractory metal starting piece of at least 99.99% purity.

11. The method for producing a refractory metal plate as defined in claim 9, wherein each of the at least three anneal heat treat temperatures are at least 875° C.

12. A method for controlling texture of sputtering targets by a process according to claim 9 wherein the step of reducing operations are performed by changing the number of forging passes and billet orientation between successive forging passes in a manner to produce a desired final texture strength and orientation.

13. A method for producing a refractory metal plate comprising the steps of:
(a) providing a refractory metal starting piece of at least 99.99% purity;
(b) first reducing the length of the refractory metal starting piece to form a first workpiece;
(c) annealing the first workpiece in a vacuum or inert gas to a first temperature of at least 1370° C.;
(d) second reducing a diameter of the first workpiece to a diameter substantially the same as a diameter of the refractory metal starting piece to form a second workpiece;
(e) annealing the second workpiece in a vacuum or inert gas to a second temperature of at least 875° C.;
(f) repeating steps (b)-(e) as necessary to achieve desired grain structure and texture uniformity;
(g) third reducing the second workpiece to a first thickness to form a first plate;
(h) fourth reducing the first thickness of the first plate to a second thickness to form a second plate; and
(i) annealing the second plate in a vacuum or inert gas to a second temperature of at least 875° C.

14. The method for producing a refractory metal plate as defined in claim 13, wherein the first reducing step comprises reducing the length of the refractory metal starting piece by at least 35%.

15. The method for producing a refractory metal plate as defined in claim 13, wherein the second reducing step comprises reducing the diameter of the first workpiece to a diameter ranging 80% to 120% of the diameter of the refractory metal starting piece.

16. The method for producing a refractory metal plate as defined in claim 13, wherein the third reducing step comprises reducing the second workpiece to a first thickness of at least 4″.

17. The method for producing a refractory metal plate as defined in claim 13, wherein the fourth reducing step comprises reducing the first thickness of the first plate to a second thickness up to 1.00″.

18. The method of claim 13 wherein the refractory metal starting piece is selected from the group consisting of tantalum, niobium, and alloys of the metals with each other and/or other metals.

19. A process for producing a metal article with fine metallurgical structure and uniform texture comprising:
a. providing a metal billet;
b. forging the billet to a desired billet thickness with about 35% to 50% reduction;
c. recrystallization annealing the billet;
d. bringing the forged billet to about room temperature;
e. side forging the billet a length substantially the same length of the metal billet;
f. recrystallization annealing the billet;
g. bringing the forged billet to about room temperature;
h. rolling the billet to plate with a reduction in thickness per rolling pass sufficient to provide near uniform strain distribution; and
i. recrystallization annealing the plate.

20. A process according to claim 19 wherein the billet is forged at a temperature below the minimum temperature of recrystallization.

21. A process according to claim 19 wherein the billet is forged in two or more forging steps with successive decrease and increase in billet diameter followed by applying an annealing heat treat after each forging step.

22. A process according to claim 19 wherein the metal billet comprises tantalum, niobium and their alloys of at least 99.99% purity.

23. A sputtering target as made according to the process of claim 19.

24. A sputtering target made by a process including forging, rolling and annealing having a target surface comprising:
a) grain size less than about 40 microns; and
b) substantially uniform structure and texture at any location.

25. A sputtering target according to claim 24 comprising tantalum, niobium and their alloys of at least 99.99% purity.
